(19) United States
(12) Patent Application Publication
(10) Pub. No.: US 2005/0285245 A1
(43) Pub. Date: Dec. 29, 2005

(54) Substrate strip for a transparent package

(75) Inventors: Jen-Chieh Kao, Kaohsiung (TW); Kuo-Hua Chen, Penghu County (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaohsiung (TW)

(21) Appl. No.: 11/135,355

(22) Filed: May 24, 2005

(30) Foreign Application Priority Data
Jun. 29, 2004 (TW) 93119070

(51) Int. Cl. H01L 23/62

(52) U.S. Cl. 257/678

(57) ABSTRACT

A substrate strip for a transparent package has a top surface, a bottom surface and an injection region through the top and bottom surface. The top surface includes a plurality of package regions and a plurality of runner regions. The injection region is disposed between the package regions and is coupled to the runner regions. The injection region has a sidewall with a releasing layer for preventing the residual of clear compound from remaining at the injection region of the substrate strip.

This application claims the benefit of Taiwan application Serial No. 93119070, filed Jun. 29, 2004, the subject matter of which is incorporated herein by reference.

### BACKGROUND OF THE INVENTION

1. Field of the Invention

The invention relates in general to a substrate strip, and more particularly to a substrate strip for a transparent package.

2. Description of the Related Art

There are more and more photoelectric components and sensing components using transparent packages. For example, a substrate strip used in a land grid array (LGA) package is shown in FIG. 1. A substrate strip 10 includes a plurality of package regions 11 and a plurality of runner regions 12. Each runner region 12 is coupled to the corresponding package region 11 and is extended to one side of the substrate strip 10. Referring to FIGS. 2 and 3, when the substrate strip 10 and a clear compound 20 are used to package a plurality of chips 30, two substrate strips 10 with the chips 30 fixed thereon are disposed at a molding device 40. The molding device 40 includes a top mold plate 41, a bottom mold plate 42 and a plurality of plunger 43. The bottom mold plate 42 has a plurality of plunger openings 44 for receiving the plungers 43. Referring to FIG. 3, when the top mold plate 41 and the bottom mold plate 42 are combined together, a plurality of runners 45 are formed and coupled to the runner regions 12 of the substrate strips 10. When the plungers 43 pushes the clear compound 20 upwards, the clear compound 20 is formed on the package regions 11 of the substrate strips 10 via the runners 45 and the runner regions 12 of the substrate strip 10 to encapsulate the chips 30. Due to a lower denseness of the clear compound 20 compared with the ordinary conventional molding compound and due to the occurrence of clearances because the above packaging process is achieved by matching multiple substrate strips 10 to the molding device 40, the clear compound 20 is likely to flood severely in the vicinity of the runner regions 12 during the long path of injection. Consequently, after the mold is released, the clear compound 20 still tightly sticks to the runner regions 12 of the substrate strips 10. Therefore, a large force needs to be applied when removing the residual of the clear compound 20 remained on the plunger openings 44, the runners 45, and the runner regions 12. Particularly when stripping off the clear compound 20 from the runner regions 12, the flooded clear compound 20 in the vicinity of the runner regions 12 will drag the substrate strips 10, causing damage to the solder mask layer and the circuit layer of the substrate strips 10 and making it extremely difficult to stripping off the compound.

### SUMMARY OF THE INVENTION

A main object of the invention is to provide a substrate strip for a transparent package, including an injection region disposed among a plurality of package regions of a substrate strip and a releasing layer formed on the sidewall of the injection region for reducing the flooding of a clear compound around a runner region, so that no residual of clear compound will not be remained at the injection region after encapsulation and the substrate strip will not be damaged due to the removal of the clear compound residual.

A second object of the invention is to provide a substrate strip for a transparent package. The substrate strip has a plurality of recessions connected with the injection region and extending to the runner regions. The recessions are recessed and corresponding to the package region so as to shorten the length of the runner region and reduce the residual of a clear compound and the area of the runner region that contact the clear compound, so that the clear compound will not flood in the vicinity of the runner regions and that the clear compound residual can be easily stripped off from the substrate.

The substrate strip for the transparent package according to the invention includes a top surface, a bottom surface and an injection region linking the top and bottom surfaces. The substrate strip includes a plurality of package regions and a plurality of runner regions disposed on the top surface. The injection region is disposed between the package regions and is coupled to the runner regions. The injection region has a sidewall with a releasing layer for preventing the residual of clear compound from remaining at the injection region of the substrate strip.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a front view of a conventional substrate strip;

FIG. 2 (Prior Art) is a front view of the conventional substrate strip disposed on a bottom mold plate;

FIG. 3 (Prior Art) is a cross-sectional views of the conventional substrate strip disposed at a molding device;

FIG. 4 is a front view of the substrate strip for the transparent package according to a preferred embodiment of the invention;

FIG. 5 is a cross-sectional view of the substrate strip taken along line 5-5 of FIG. 4 according to a preferred embodiment of the invention; and

FIG. 6 is a cross-sectional view of the substrate strip disposed at a molding device according to a preferred embodiment of the invention.

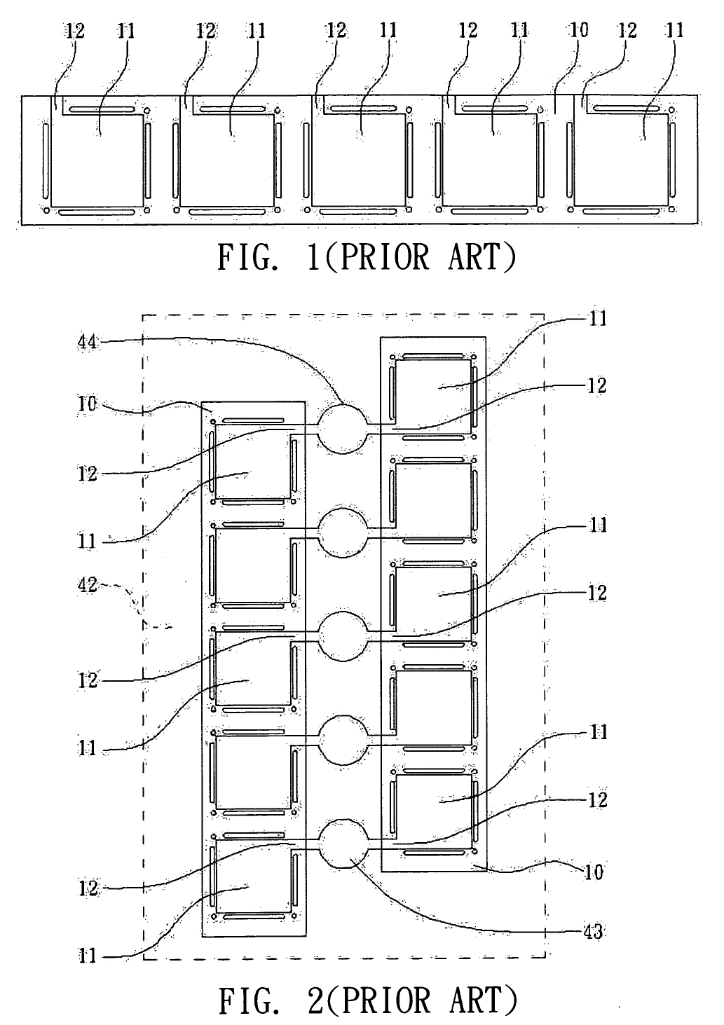

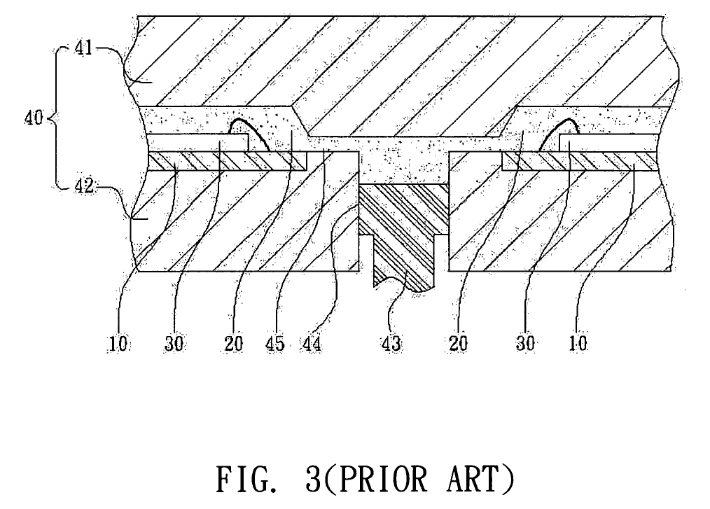

### DETAILED DESCRIPTION OF THE INVENTION

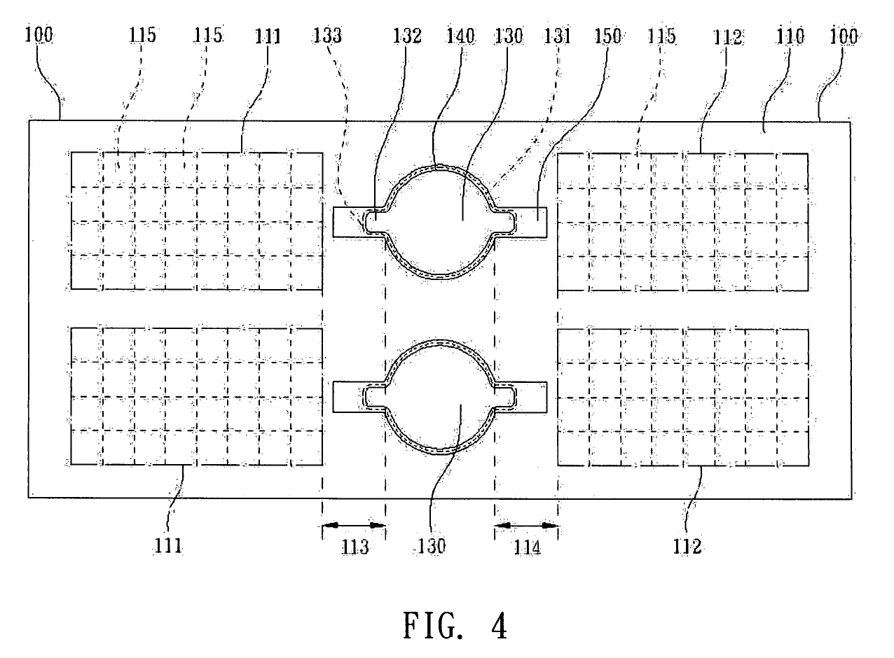

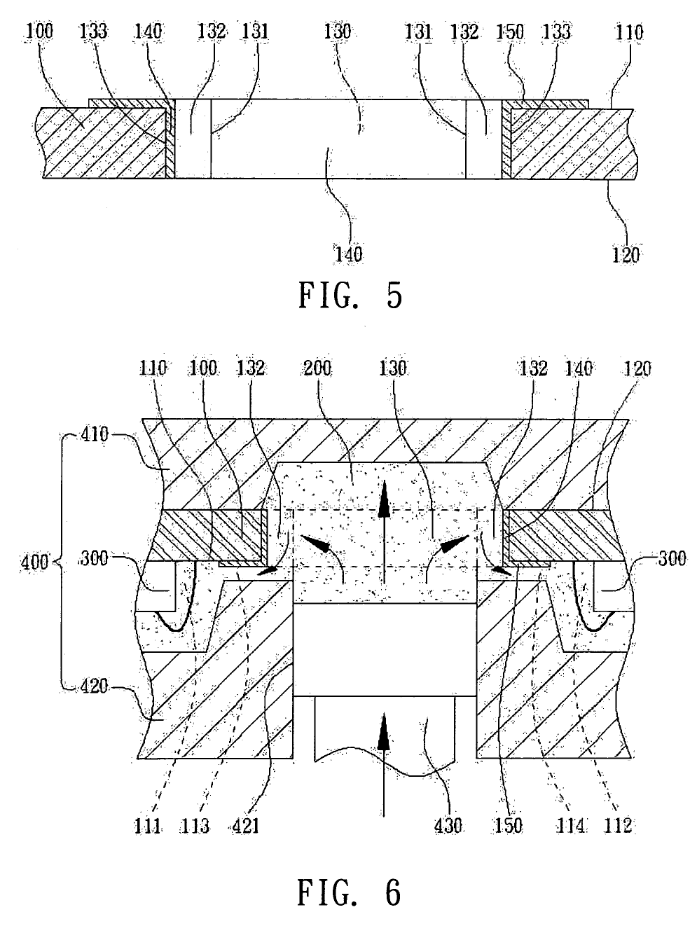

Referring to FIGS. 4 and 5, a substrate strip 100 for a transparent package, which can be made from flame-retardant epoxy-glass fabric composite resin (FR-4, FR-5) or bismaleimide triazine (BT), has a top surface 110, a bottom surface 120 and an injection region 130. The injection region 130 links the top surface 110 and the bottom surface 120. The top surface 110 includes at least a first package region 111, at least a second package region 112, at least a first runner region 113, and at least a second runner region 114. The injection region 130 is disposed between the first package regions 111 and the second package region 112. That is, the first package region 111 and the second package region 112 are paired to be symmetrically disposed on two opposite sides of the injection region 130. Both the first package regions 111 and the second package region 112 include a plurality of package units 115. The first runner region 113 is disposed between and coupled with the corresponding first package region 111 and the injection region 130. The second runner region 114 is disposed between and coupling the corresponding second package region 112 and the injection region 130. The first runner region 113 and the second runner region 114 are preferably fan-shaped runner region converging toward the injection region 130. In the present embodiment, the scale of the injection region 130 is preferably ranging from 8 to 20 mm. Preferably, the injection region 130 is disposed at the central position of the substrate strip 100 and disposed between the first and second package regions. The injection region 130 has a sidewall 131 on which a releasing layer 140 is formed. The releasing layer 140 can be a metal layer made by a material selected from a group of gold, nickel and combination thereof, such as a gold layer, a nickel layer or a nickel-gold layer. The releasing layer 140 is extended to the top surface 110. The width of the releasing layer 140 on the top surface 110 is at least above 100 μm. Preferably, the releasing layer 140 of the top surface 110 surrounds the periphery of the injection region 130. In the present embodiment, the substrate strip 100 has a plurality of recessions 132, connected with the injection region 130 and extending to the first runner region 113 and the corresponding second runner region 114 thereof. The recessions 132 are recessed and corresponding to the first runner region 113 and the second runner region 114 so as to shorten the length of the injection path of the compound between the first runner region 113 and the second runner region 114. Each recession 132 has a sidewall 133. The releasing layer 140 is preferably formed on the sidewall 133 of the recessions 132. A releasing layer 150 is formed on the runner regions 113 and 114. Preferably, the releasing layer 150 and the releasing layer 140 are the same metal material formed in unity.

Referring to FIG. 6, when the above substrate strip 100 and a clear compound 200 are used to package a plurality of chips 300, the substrate strip 100 with the chips 300 fixed thereon is disposed at a molding device 400. The molding device 400 includes a top mold plate 410, a bottom mold plate 420 and at least a plunger 430. The bottom mold plate 420 has at least a plunger opening 421 for receiving the plunger 430. The injection region 130 of the substrate strip 100 corresponds to the plunger opening 421 of the bottom mold plate 420. After the top mold plate 410 and the bottom mold plate 420 are combined together, the plunger 430 pushes upwards. After filling up the injection region 130 of the substrate strip 100, the clear compound 200 immediately is injected into and flows through the first runner regions 113 and the second runner region 114 to fill the first package region 111 and the second package region 112 and encapsulate the chips 300. Therefore, it is not necessary for a runner to be formed between the top mold plate 410 and the bottom mold plate 420 as a conventional molding device would do. Thus, the path of the clear compound 200 from the plunger opening 421 to the first package regions 111 and the second package region 112 is largely reduced compared with the path from a conventional plunger opening to a package region. It is unlikely for the clear compound 200 to flood during the shorter path between the first runner region 113 and the second runner region 114. After the mold is released, the clear compound 200 on the first runner regions 113, the second runner region 114 and the injection region 130 is removed. That is, the residual of the clear compound 200 remained outside the first package regions 111 and the second package region 112 is removed. The releasing layer 140 formed on the sidewall 131 of the injection region 130 is extended to the top surface 110, not only making the residual of clear compound 200 remained on the injection region 130 easier to be removed, but also preventing the residual of the clear compound 200 from remaining at the injection region 130. In the present embodiment, the sidewall 131 of the injection region 130 has the recession 132 which are recessed and corresponding to the first runner region 113 and the corresponding second runner region 114 thereof so as to reduce the residual of the clear compound 200 and the contact area between the first runner region 113 and the second runner region 114, so the residual of the clear compound 200 can be easily stripped off.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A substrate strip for a transparent package, comprising:
a top surface and a bottom surface opposite to the top surface;
a plurality of package regions, disposed on the top surface;
a plurality of runner regions, disposed on the top surface;
an injection region, linking the top surface and the bottom surface and disposed among the package regions; and
a releasing layer, formed on a sidewall of the injection region;
wherein each of the runner regions couples one of the corresponding package regions with the injection region.

2. The substrate strip for a transparent package according to claim 1, further comprising a plurality of recessions connected with the injection region and extending to the runner regions.

3. The substrate strip for a transparent package according to claim 2, wherein the releasing layer is formed on sidewalls of the recessions.

4. The substrate strip for a transparent package according to claim 2, wherein the recessions correspond to the package regions.

5. The substrate strip for a transparent package according to claim 1, wherein the releasing layer is extended from the sidewall of the injection region to the top surface.

6. The substrate strip for a transparent package according to claim 1, wherein the injection region is disposed at the central position of the substrate strip.

7. The substrate strip for a transparent package according to claim 1, wherein the package regions are paired to be symmetrically disposed at two opposite sides of the injection region.

8. The substrate strip for a transparent package according to claim 1, wherein each of the package regions comprises a plurality of package units.

9. The substrate strip for a transparent package according to claim 1, wherein the releasing layer is made of a material selected from a group of gold, nickel and combination thereof.

10. The substrate strip for a transparent package according to claim 1, further comprising another releasing layer formed on the runner regions.

11. The substrate strip for a transparent package according to claim 10, wherein the another releasing layer of the runner regions and the releasing layer of the injection region are formed in unity.
